(19) United States
(12) Patent Application Publication
(10) Pub. No.: US 2005/0016467 A1
(43) Pub. Date: Jan. 27, 2005

(54) System and method for dry chamber temperature control

(75) Inventors: Yi-Li Hsiao, Dalin Jen (TW); Mei-Sheng Zhou, Singapore (SG); Chin-Hsin Peng, Hsin-Chu City (TW); Chien-Ling Huang, Hsin-Chu (TW); Tse-Yi Chen, Hsin-Chu City (TW); Chun-Yi Lee, Hsin-Chu (TW); Hsueh-Chang Wu, Taipei (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/626,998

(22) Filed: Jul. 24, 2003

(51) Int. Cl. C23C 16/00

(52) U.S. Cl. 118/728; 118/724

(57) ABSTRACT

A system and method which is capable of compensating for unintended elevations in process temperatures induced in a substrate during a semiconductor fabrication process in order to reduce or eliminate disparities in critical dimensions of device features. The system may be a plasma etching system comprising a process chamber containing an electrostatic chuck (ESC) for supporting a wafer substrate. A chiller outside the process chamber includes a main coolant chamber, which contains a main coolant fluid, as well as an compensation coolant chamber, which contains an compensation coolant fluid. A main circulation loop normally circulates the main coolant fluid from the main coolant chamber through the electrostatic chuck to maintain the chuck at a desired set point temperature.

### FIELD OF THE INVENTION

The present invention relates to reaction chambers used in the fabrication of integrated circuits on semiconductor wafer substrates. More particularly, the present invention relates to a system and-method for constraining temperatures of a substrate support in a reaction chamber within narrow limits to minimize thermal deviation of the substrate during reaction processes.

### BACKGROUND OF THE INVENTION

Integrated circuits are formed on a semiconductor substrate, which is typically composed of silicon. Such formation of integrated circuits involves sequentially forming or depositing multiple electrically conductive and insulative layers in or on the substrate. Etching processes may then be used to form geometric patterns in the layers or vias for electrical contact between the layers. Etching processes include “wet” etching, in which one or more chemical reagents are brought into direct contact with the substrate, and “dry” etching, such as plasma etching.

Various types of plasma etching processes are known in the art, including plasma etching, reactive ion (RI) etching and reactive ion beam etching. In each of these plasma processes, a gas is first introducted into a reaction chamber and then plasma is generated from the gas. This is accomplished by dissociation of the gas into ions, free radicals and electrons by using an RF (radio frequency) generator, which includes one or more electrodes. The electrodes are accelerated in an electric field generated by the electrodes, and the energized electrons strike gas molecules to form additional ions, free radicals and electrons, which strike additional gas molecules, and the plasma eventually becomes self-sustaining. The ions, free radicals and electrons in the plasma react chemically with the layer material on the semiconductor wafer to form residual products which leave the wafer surface and thus, etch the material from the wafer.

In the fabrication of semiconductor devices, particularly sub-micron scale semiconductor devices, profiles obtained in the etching process are very important. Careful control of a surface etch process is therefore necessary to ensure directional etching. In conducting an etching process, when an etch rate is considerably higher in one direction than in the other directions, the process is called anisotropic. A reactive ion etching (RIE) process assisted by plasma is frequently used in an anisotropic etching of various material layers on top of S semiconductor substrate. In plasma enhanced etching processes, the etch rate of a semiconductor material is frequently larger than the sum of the individual etch rates for ion sputtering and individual etching due to a synergy in which chemical etching is enhanced by ion bombardment.

To avoid subjecting a semiconductor wafer to high-energy ion bombardment, the wafer may also be placed downstream from the plasma and outside the discharge area. Downstream plasma etches more in an isotropic manner since there are no ions to induce directional etching. The downstream reactors are frequently used for removing resist or other layers of material where patterning is not critical. In a downstream reactor, radio frequency may be used to generate long-lived radioactive species for transporting to a wafer surface located remote from the plasma. Temperature control problems and radiation damage are therefore significantly reduced in a downstream reactor. Furthermore, the wafer holder can be heated to a precise temperature to increase the chemical reaction rate, independent of the plasma.

In a downstream reactor, an electrostatic wafer holding device known as an electrostatic chuck is frequently used. The electrostatic chuck attracts and holds a wafer positioned on top electrostatically. The electrostatic chuck method for holding a wafer is highly desirable in the vacuum handling and processing of wafers. An electrostatic chuck device can hold and move wafers with a force equivalent to several tens of Torr pressure, in contrast to a conventional method of holding wafers by a mechanical clamping method.

Referring to the schematic of FIG. 1, a conventional plasma etching system is generally indicated by reference numeral 10. The etching system 10 includes a reaction chamber 12 having a typically grounded chamber wall 14. An electrode, such as a planar coil electrode 16, is positioned adjacent to a dielectric plate 18 which separates the electrode 16 from the interior of the reaction chamber 12. Plasma-generating source gases are introduced into the reaction chamber 12 by a gas supply (not shown). Volatile reaction products and unreacted plasma species are removed from the reaction chamber 12 by a gas removal mechanism, such as a vacuum pump (not shown).

The dielectric plate 18 illustrated in FIG. 1 may serve multiple purposes and have multiple structural features, as is well known in the art. For example, the dielectric plate 18 may include features for introducing the source gases into the reaction chamber 12, as well as those structures associated with physically separating the electrode 16 from the interior of the chamber 12.

Electrode power such as a high voltage signal, provided by a power generator such as an RF (radio frequency) generator (not shown), is applied to the electrode 16 to ignite and sustain a plasma in the reaction chamber 12. Ignition of a plasma in the reaction chamber 12 is accomplished primarily by electrostatic coupling of the electrode 16 with the source gases, due to the large-magnitude voltage applied to the electrode 16 and the resulting electric fields produced in the reaction chamber 12. Once ignited, the plasma is sustained by electromagnetic induction effects associated with time-varying magnetic fields produced by the alternating currents applied to the electrode 16. The plasma may become self-sustaining in the reaction chamber 12 due to the generation of energized electrons from the source gases and striking of the electrons with gas molecules to generate additional ions, free radicals and electrons. A semiconductor wafer 20 is positioned in the reaction chamber 12 and is supported by an ESC (electrostatic chuck) 22. The ESC 22 is typically electrically-biased to provide ion energies that are independent of the RF voltage applied to the electrode 16 and that impact the wafer 20.

As further shown in FIG. 1, the plasma etching system 10 typically includes a temperature control system 23 which may include a chiller 24 that contains a supply of a coolant fluid 26. The coolant fluid 26 is maintained at a desired set point temperature for the ESC 22 and the wafer 20, typically about 60° C. A coolant delivery line 28 distributes the coolant fluid 26 to the ESC 22, where the coolant is distributed throughout coolant channels (not shown) in the ESC 22 to maintain the ESC 22, and thus, the wafer 20 supported thereon, at-the desired set point temperature. Typically, the set point temperature for the ESC 22 is 60° C., the same temperature as the coolant fluid 26. After it is distributed through the ESC 22, the coolant fluid 26 is returned to the chiller 24 through a coolant return line 30. Accordingly, the coolant fluid 26 is continually circulated from the chiller 24, through the ESC 22 and back to the chiller 24 to maintain the ESC 22, and thus, the wafer 20, at the desired set temperature.

In the graph of FIG. 2, ESC temperature (progressing vertically along the Y-axis) is plotted as a function of reaction time (progressing rightward along the X-axis) which elapses during a typical plasma etch reaction. The horizontal line 32 represents the set point temperature for the ESC, typically about 60° C., whereas the angled line 34 represents a temporary elevation in ESC temperature during the plasma induction phase of the etching process. Accordingly, at t1, when the plasma induction phase begins, the temperature of the electrostatic chuck gradually rises by as many as 5 degrees Celsius or more, until the ESC temperature reaches a peak when the plasma induction phase ends, at t2. From t2 to t3, the ESC temperature drops back to the set point temperature.

For advanced semiconductor technology, precise temperature control is of utmost importance since unintended variations in process temperatures may result in excessive oxide growth on the substrate, among other considerations. Critical dimension (CD) shifts occur at a rate of over 1 nm (nanometer) per degree Celcius change in reaction temperature, and within-wafer CD shifts as great as 3 nm have been known due to process temperature variations. As device features become smaller and smaller, these unintended process temperature variations become increasingly problematic. Conventional temperature control methods and systems are capable of controlling unintended shifts in ESC temperatures to within about 5 degrees Celsius. Accordingly, a system and method is needed which is capable of controlling ESC temperature shifts to within 0.5 degrees Celsius.

An object of the present invention is to provide a system and method for constraining temperatures of a substrate within desired limits.

Another object of the present invention is to provide a system and method for preventing or minimizing unintended variations in temperature of a semiconductor wafer substrate during a plasma etch process.

Still another object of the present invention is to provide a system and method which provides thermal compensation for elevated temperatures induced in an electrostatic chuck or other wafer holder during a semiconductor fabrication process.

Yet another object of the present invention is to provide a system and method which eliminates or minimizes disparities in critical dimension (CD) of device features due to unintended temperature variations during a semiconductor fabrication process.

A still further object of the present invention is to provide a system and method which provides compensation for elevated temperatures induced in an electrostatic chuck or other wafer holder as a result of plasma induction during a plasma etch process.

### SUMMARY OF THE INVENTION

In accordance with these and other objects and advantages, the present invention is generally directed to a system and method which is capable of compensating for unintended elevations in process temperatures induced in a substrate during a semiconductor fabrication process in order to reduce or eliminate disparities in critical dimensions of device features. The system may be a plasma etching system comprising a process chamber that contains an electrostatic chuck (ESC) for supporting a wafer substrate. A chiller outside the process chamber includes a main coolant chamber, which contains a main coolant fluid, as well as a compensation coolant chamber, which contains a compensation coolant fluid. A main circulation loop normally circulates the main coolant fluid from the main coolant chamber through the electrostatic chuck to maintain the chuck at a desired set point temperature during the etching process. When plasma induction begins in the process chamber, a compensation circulation loop circulates the compensation coolant fluid, which has a temperature less than that of the main coolant fluid, through the chuck, to cool the chuck and cancel the heating effects of the plasma. Consequently, the chuck; and thus, the wafer supported thereon, is substantially maintained at the set point temperature throughout the etching process.

### BRIEF DESCRIPTION OF THE DRAWINGS

The invention will now be described, by way of example, with reference to the accompanying drawings, in which:

FIG. 1 is a sectional schematic view of a typical conventional plasma etching system;

FIG. 2 is a graph illustrating plasma-induced elevation of ESC temperatures during an etching process;

FIG. 3 is a sectional schematic view of a plasma etching system of the present invention;

FIG. 4 is a graph illustrating an actual temperature characteristic line achieved through use of the temperature control system of the present invention and a main temperature characteristic line and temperature compensation characteristic line shown as mirror images of each other on opposite sides of the actual temperature characteristic line

FIG. 5 is a schematic view of another embodiment of a temperature control system of the present invention;

FIG. 5A is a cross-sectional view of a P/N junction module of the temperature control system of FIG. 5;

FIG. 6 is a graph illustrating closing of valves in the temperature control system plotted as a function of voltage applied to the valves; and

FIG. 7 is a graph illustrating opening of valves in the temperature control system plotted as a function of voltage applied to the valves.

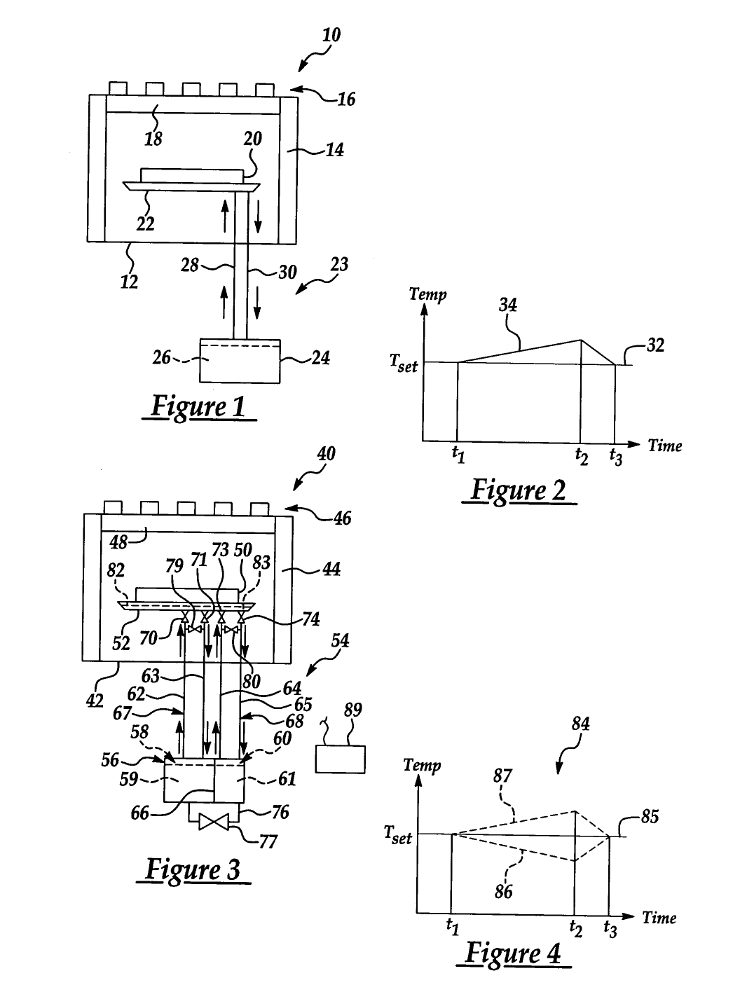

### DESCRIPTION OF THE PREFERRED EMBODIMENTS

The present invention has particularly beneficial utility in preventing or minimizing plasma-induced elevations in process temperatures of a wafer substrate during a plasma dry etching process in the fabrication of semiconductor integrated circuits. However, the invention is not so limited in application, and while references may be made to such plasma etching processes, the invention is more generally applicable to maintaining process temperatures within desired limits in a variety of applications.

Referring to FIG. 3, an illustrative embodiment of a plasma etching system in implementation of the present invention is generally indicated by reference numeral 40. While the plasma etching system 40 is typically a dry etching system and may include the particular features hereinafter described, it is understood that the present invention may be equally applicable to process systems having features in addition to or other than those hereinafter described. Accordingly, the following description is not intended to limit the present, invention in any manner.

The plasma etching system 40 includes a reaction chamber 42 having a typically grounded chamber wall 44. An electrode, such as a planar coil electrode 46, may be positioned adjacent to a dielectric plate 48 which separates the electrode 46 from the interior of the reaction chamber 42. The dielectric plate 48 may serve multiple purposes and have multiple structural features, as is well known in the art. For example, the dielectric plate 48 may include features for introducing source gases into the reaction chamber 42, as well as structures associated with physically separating the electrode 46 from the interior of the chamber 42. An electrostatic chuck (ESC) 52 is included inside the reaction chamber 42 for supporting a semiconductor wafer 50 thereon during an etching process carried out on the wafer 50, as hereinafter described. The ESC 52 is typically electrically-biased to provide ion energies that are independent of the RF voltage applied to the electrode 46 and that impact the wafer 50.

As further shown in FIG. 3, the plasma etching system 40 includes a temperature control system 54 in accordance with the present invention. The temperature control system 54 includes a chiller 56 that contains a main coolant chamber 58 which is separated from a compensation coolant chamber 60 by an internal partition 66 in the chiller 56. In application, as hereinafter described, the main coolant chamber 58 contains a supply of main coolant fluid 59, whereas the compensation coolant chamber 60 contains a supply of compensation coolant fluid 61. In a typical embodiment, the main coolant chamber 58 has a volume of about 2-3 gallons, whereas the compensation coolant chamber 60 has a volume of about ¼ the volume of the main coolant chamber 58, typically about ½ gal-¾ gal.

A main circulation loop 67 of the temperature control system 54 includes a main coolant delivery line 62 that confluently connects the main coolant chamber 58 of the chiller 56 to the ESC 52 of the reaction chamber 42, typically through a delivery line valve 70, which may be a solenoid valve. The main coolant delivery line 62 is disposed in fluid communication with a network of main coolant channels 82 which are distributed throughout the ESC 52 for substantially uniformly imparting a temperature of the main coolant 59 to the ESC 52 as the main coolant 59 flows through the main coolant channels 82, as hereinafter further described. The main circulation loop 67 further includes a main coolant return line 63 that confluently connects the main coolant channels 82 in the ESC 52 to the main coolant chamber 58 typically through a return line valve 71, which may be a solenoid valve. The main coolant delivery line 62 may be confluently connected to the main coolant return line 63 through a line connecting valve 79. A controller 89 for the plasma etching system 40 may be operably connected to the delivery line valve 70 and return line valve 71 for automatic operation of the valves 70 and 71, respectively.

A compensation circulation loop 68 of the temperature control system 54 includes a compensation coolant delivery line 64 that confluently connects the compensation coolant chamber 60 of the chiller 56 to the ESC 52 of the reaction chamber 42, typically through a typically solenoid delivery line valve 73 which is typically operably connected to the controller 89 for automatic operation. The compensation coolant delivery line 64 is disposed in fluid communication with a network of compensation coolant channels 83 which are distributed throughout the ESC 52 for absorption of heat energy from the ESC 52 by the compensation coolant fluid 61 as the compensation coolant fluid 61 flows through the compensation coolant channels 83, as hereinafter further described. The compensation circulation loop 68 further includes an compensation coolant return line 65 that confluently connects the ESC 52 back to the compensation coolant chamber 60 typically through a typically solenoid return line valve 74 which is typically operably connected to the controller 89 for automatic operation. The compensation coolant delivery line 64 may be confluently connected to the compensation coolant return line 65 through a line connecting valve 80. An interchamber line 76, typically fitted with an interchamber valve 77, may confluently connect the main coolant chamber 58 directly to the compensation coolant chamber 60.

Referring again to FIG. 3, in application of the temperature control system 54, the main coolant chamber 58 contains a supply of the main coolant fluid 59, whereas the compensation coolant chamber 60 contains a supply of the compensation coolant fluid 61. The main coolant fluid 59 and the compensation coolant fluid 61 may be any type of cooling fluid including but not limited to water. The main coolant fluid 59 is maintained at a desired set point temperature for the ESC 52 and the wafer 50 in a plasma etch process, typically about 60° C., whereas the compensation coolant fluid 61 is maintained at a temperature which is about 5° C. to about 10° C. lower than the main coolant fluid 59, typically at about 50° C. The semiconductor wafer 50 placed on the ESC 52 for etching of a layer or layers on the wafer 50.

As the etching process commences, the reaction chamber 42 is heated to the predetermined set point temperature, such as 60° C., for optimal etching of the wafer 50. Simultaneously, the main coolant fluid 59, maintained at the set point temperature (60° C. in this case) in the main coolant chamber 58 of the chiller 56, is continually circulated from the main coolant chamber 58, through the main coolant delivery line 62 and open delivery line valve 70, respectively, and distributed throughout the main coolant channels 82 of the ESC 52, as the delivery line valve 70 and the return line valve 71 remain open typically by operation of the controller 89. The main coolant fluid 59 is finally returned to the main coolant chamber 58 through the open return line valve 71 and the main coolant return line 63. As it circulates through the main coolant channels 82, the main coolant 59 maintains the ESC 52 and the wafer 50 supported thereon at the 60° C. set point temperature for optimum etching of the wafer 50. While the main coolant fluid 59 is continually circulated through the main circulation loop 67, the compensation coolant fluid 61 initially remains in the compensation coolant chamber 60, as the delivery line valve 73 and the return line valve 74 of the compensation circulation loop 68 remain closed typically by the controller 89.

At the beginning of the plasma-induction phase of the etching process, plasma-generating source gases are introduced into the reaction chamber 42 by a gas supply (not shown), typically in conventional fashion. Volatile reaction products and unreacted plasma species are removed from the reaction chamber 42 by a gas removal mechanism, such as a conventional vacuum pump (not shown). Electrode power such as a high voltage signal, provided by a power generator such as an RF (radio frequency) generator (not shown), is applied to the electrode 46 to ignite and sustain a plasma in the reaction chamber 42. Ignition of a plasma in the reaction chamber 42 is accomplished primarily by electrostatic coupling of the electrode 46 with the source gases, due to the large-magnitude voltage applied to the electrode 46 and the resulting electric fields produced in the reaction chamber 42. Once ignited, the plasma is sustained by electromagnetic induction effects associated with time-varying magnetic fields produced by the alternating currents applied to the electrode 46. The plasma may become self-sustaining in the reaction chamber 42 due to the generation of energized electrons from the source gases and striking of the electrons with gas molecules to generate additional ions, free radicals and electrons.

Formation of the plasma causes an inherent temperature rise inside the reaction chamber 42, and this increase in temperature in the reaction chamber 42 in turn tends to raise the temperature of the ESC 52 and the wafer 50 by convection and must be counteracted for optimum etching of the wafer 50. Accordingly, at the same time the plasma induction phase of the etching process begins, the controller 89 autmatically opens the delivery line valve 73 and the return line valve 74 of the compensation circulation loop 68. The compensation coolant fluid 61, maintained at the cooling temperature (50° C. in this case) in the compensation coolant chamber 60 of the chiller 56 is continually circulated from the compensation coolant chamber 60, through the compensation coolant delivery line 64 and open delivery line valve 73, respectively, and distributed throughout the compensation coolant channels 83 in the ESC 52. As it is continually distributed throughout the compensation coolant channels 83 in the ESC 52, the compensation coolant fluid 61 absorbs excess heat imparted to the ESC 52 by the plasma and thus, maintains the ESC 52, and thus, the wafer 50 supported thereon, substantially at the desired set point temperature. The compensation coolant fluid 61 is returned to the compensation coolant chamber 60 through the open return line valve 74 and the compensation coolant return line 65, where it is cooled back to the cooling temperature (50° C. in this case) and re-circulated through the compensation circulation loop 68. Coolant fluid may be distributed from the main coolant chamber 58, through the interchamber line 76 and into the compensation coolant chamber 60, as needed, by opening the interchamber valve 77.

In the graph 84 of FIG. 4, ESC temperature (progressing vertically along the Y-axis) is plotted as a function of reaction time (progressing rightward along the X-axis) which elapses during a plasma etch reaction in implementation of the temperature control system 54 of the present invention. The horizontal line 85 represents the set point temperature for the ESC 85 during the plasma etching process (60° C. in this case), whereas the downwardly-sloped temperature compensation characteristic curve 86 represents the temperature of the ESC 85 which would be caused by the cooling effects of the temperature control system 54 in the absence of a plasma-induction phase during the etching process. The upwardly-sloped main temperature characteristic curve 87 represents an elevation in ESC temperature which would otherwise occur during the plasma induction phase of the etching process without the cooling effects of the temperature control system 54. When the plasma induction phase begins, as indicated at t1, thereby elevating process temperatures in the reaction chamber, the temperature of the electrostatic chuck remains substantially constant, typically at 60° C.,±0.5° C. This set point temperature is maintained through the end of the plasma etching phase, at t2, and through completion of the etching process at t3.

According to a method of the present invention, a main temperature characteristic curve 87 on a graph 84, having ESC temperature plotted vs. time, is first obtained by operating the plasma etching system 40 and cooling the ESC 52 using the main coolant fluid 59 without the compensation coolant fluid 61. A temperature compensation characteristic curve 86 is then obtained by forming a mirror reflection of the main temperature characteristic curve 87 below the horizontal set point temperature line 85. Accordingly, the main temperature characteristic curve 87 and the temperature compensation characteristic curve 86 are symmetrical with respect to each other above and below, respectively, the horizontal set point line 85. The temperature control system 54 is then operated according to the temperature compensation characteristic curve 86 to maintain the ESC 52 at a substantially constant set point temperature as indicated by the horizontal line 85.

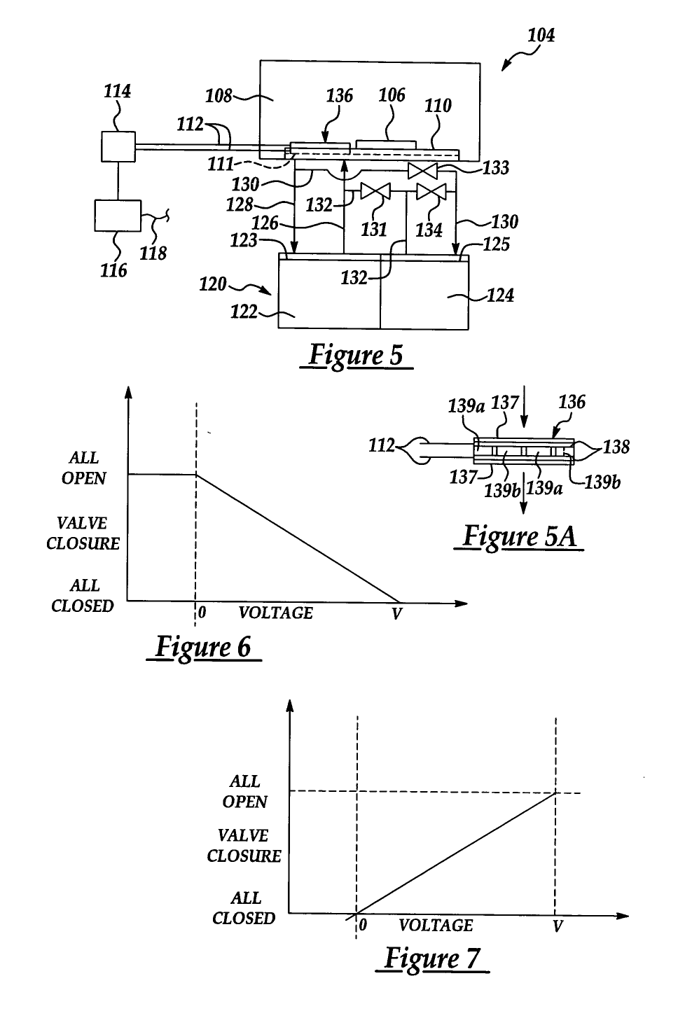

Referring next to FIG. 5-9, another embodiment of the temperature control system 120 of the present invention includes a main coolant tank 122 which contains a supply of main coolant 123 and a compensation coolant tank 124 which contains a supply of compensation coolant 125. A main coolant delivery line 126 connects the main coolant tank 122 in fluid communication with coolant channels 111 extending through an electrostatic chuck (ESC) 110 of a plasma etch system 104 to be cooled in a process chamber 108, for example, as heretofore described with respect to FIG. 3. A main coolant return line 128 further connects the ESC 110 in fluid communication with the main coolant tank 122.

A compensation coolant delivery line 132 connects the compensation coolant tank 124 to the main coolant delivery line 126. A valve 131 may be provided in the compensation coolant delivery line 132. A compensation coolant return line 130 extends from the main coolant return line 128 and is provided in fluid communication with the compensation coolant tank 124. A valve 133 may be provided in the compensation coolant return line 130. A circulation valve 134 may be provided between the compensation coolant delivery line 132 and the compensation coolant return line 130 to facilitate circulation of compensation coolant 124 through the compensation coolant delivery line 132, valve 134, compensation coolant return line 130 and back into the compensation coolant tank 124, respectively.

A P/N junction module 136 is provided in thermal contact with the ESC 110 and is operably connected to a power supply 114 through wiring 112. The power supply 114 is connected to a controller 116, which is electrically connected to the valve 131, valve 133 and circulation valve 134 through wiring 118. As hereinafter described, the P/N junction module 136 measures the temperature of the coolant flowing through the coolant channels 111 in the ESC 110 and opens or closes the valve 131, the valve 133 and/or the circulation valve 134, through the controller 116 as necessary to micro-adjust the temperature of the ESC 110.

As shown in FIG. 5A, the P/N junction module 136 includes spaced-apart sheets of electrical insulation 137 and a typically copper, electrically-conductive sheet 138 provided on the inner surface of each electrical isulation sheet 137. Multiple p-type semiconductors 139a and n-type semiconductors 139b are sandwiched between the electrically-conductive sheets 138. The wiring 112 is connected to the respective electrically-conductive sheets 138.

Referring to FIGS. 5, 8 and 9, in application of the temperature control system 120, the main coolant fluid 123 is maintained at a desired set point temperature for the ESC 110 in a plasma etch process, typically about 60° C., whereas the compensation coolant 125 is maintained at a temperature which is about 5° C. to about 10° C. lower than the main coolant fluid 123, typically at about 50° C. A semiconductor wafer 106 is placed on the ESC 110 for etching of a layer or layers on the wafer 106 in the plasma etch system 104. As the etching process commences, the reaction chamber 108 is heated to the predetermined set point temperature, such as 60° C., for optimal etching of the wafer 106. The P/N junction module 136, through the controller 116, normally maintains a potential of zero voltage to the valves 131, 133 and 134, respectively, such that the valves 131, 133 are closed, as shown in FIG. 9, and the valve 134 is open, as shown in FIG. 8. Accordingly, the main coolant fluid 123, maintained at the set point temperature (60° C. in this case) in the main coolant chamber 122, is continually circulated from the main coolant chamber 122, through the main coolant delivery line 126 and distributed throughout the main coolant channel 111 of the ESC 110, as the valve 131 and the valve 133 remain closed typically by operation of the controller 116. The main coolant fluid 123 is finally returned to the main coolant chamber 122 through the main coolant return line 128. As it circulates through the main coolant channels 111, the main coolant 123 maintains the ESC 110 and the wafer 106 supported thereon at the 60° C. set point temperature for optimum etching of the wafer 106. While the main coolant fluid 123 is continually circulated through the main circulation channel 111, the compensation coolant fluid 115 initially remains in the compensation coolant chamber 124, as the valve 131 of the compensation coolant delivery line 132 and the valve 133 of the compensation coolant return line 130 remain closed typically by the controller 116.

At the beginning of the plasma-induction phase of the etching process, plasma-generating source gases are introduced into the reaction chamber 108 by a gas supply (not shown), typically in conventional fashion. Formation of the plasma causes an inherent temperature rise inside the reaction chamber 108, and this increase in temperature in the reaction chamber 108 in turn tends to raise the temperature of the ESC 110 and the wafer 106. Accordingly, the P/N junction module 136 senses the temperature of the ESC 136 and causes the controller 116 to apply a positive voltage to the valves 131, 133 and 134, respectively. As shown in FIG. 8, this causes the valve 134 to close to a degree which depends on the magnitude of the voltage applied to the valve 134. Simultaneously, as shown in FIG. 9, the positive voltage applied to the valves 131, 133 causes these valves to open the compensation coolant delivery line 132 and the compensation coolant return line 130, respectively, to a degree which depends on the magnitude of the voltage applied to the valves 131, 133. The compensation coolant 125, maintained at the cooling temperature (50° C. in this case) in the compensation coolant chamber 124, is continually circulated from the compensation coolant chamber 124, through the compensation coolant delivery line 132 and open valve 131, respectively, and main coolant delivery line 126, and distributed throughout the coolant channels 111 in the ESC 110. As it is continually distributed throughout the coolant channel 111 in the ESC 110, the compensation coolant fluid 125 absorbs excess heat imparted to the ESC 110 by the plasma and thus, maintains the ESC 110, and thus, the wafer 106 supported thereon, substantially at the desired set point temperature. The compensation coolant fluid 125 is returned to the compensation coolant chamber 125 through the open valve 133 and the compensation coolant return line 130, where it is cooled back to the cooling temperature (50° C. in this case) and re-circulated through the coolant channels 111.

As the compensation coolant 125 is circulated through the coolant channels 111, the P/N junction module 136 continually senses the temperature of the ESC 110. When the temperature of the ESC 110 rises above the set point temperature, the P/N junction module 136 applies a correspondingly higher voltage to the valves 131, 133, thereby opening these valves to facilitate distribution of a correspondingly larger volume of compensation coolant 125 through the coolant channels 111, as shown in FIG. 9. This maintains the ESC 110 at the set point temperature and facilitates micro-adjustment of the temperature of the ESC 110.

Referring again to FIG. 4, according to a method of the present invention, a main temperature characteristic curve 87 on a graph 84, having ESC temperature plotted vs. time, is first obtained by operating the plasma etching system 104 and cooling the ESC 110 using the main coolant fluid 123 without the compensation coolant fluid 125. A temperature compensation characteristic curve 86 is then obtained by forming a mirror reflection of the main temperature characteristic curve 87 below the horizontal set point temperature line 85. The temperature control system 120 is then operated according to the temperature compensation characteristic curve 86 to maintain the ESC 110 at a substantially constant set point temperature as indicated by the horizontal line 85.

While the preferred embodiments of the invention have been described above, it will be recognized and understood that various modifications can be made in the invention and the appended claims are intended to cover all such modifications which may fall within the spirit and scope of the invention.

1. A method of maintaining a substrate support at a set point temperature in a reaction chamber upon a rise in temperature of the chamber, comprising the steps of:
circulating a main coolant fluid having the set point temperature through the substrate support; and
circulating a compensation coolant fluid having a cooling temperature lower than said set point temperature through the substrate support upon the rise in temperature of the chamber.

2. The method of claim 1 wherein said set point temperature is about 60° C.

3. The method of claim 1 wherein said cooling temperature is about 50° C.

4. The method of claim 3 wherein said set point temperature is about 60° C.

5. The method of claim 1 wherein said main coolant fluid and said compensation coolant fluid each comprises water.

6. The method of claim 5 wherein said set point temperature is about 60° C.

7. The method of claim 5 wherein said coolant temperature is about 50° C.

8. The method of claim 7 wherein said set point temperature is about 60° C.

9. A method of maintaining a substrate support confluently connected to a main coolant chamber containing main coolant at a set point temperature, comprising the steps of:
circulating the main coolant through the substrate support at the set point temperature;
providing a compensation coolant chamber containing compensation coolant in fluid communication with said substrate support; and
circulating the compensation coolant from said compensation coolant chamber through the substrate support at a cooling temperature lower than said set point temperature upon a rise in temperature of the substrate support above the set point temperature.

10. The method of claim 9 wherein said set point temperature is about 60° C.

11. The method of claim 9 wherein said coolant temperature is about 50° C.

12. The method of claim 11 wherein said set point temperature is about 60° C.

13. The method of claim 9 further comprising the steps of providing a P/N junction module in thermal contact with the substrate support for sensing a temperature of the substrate support and controlling flow of the compensation coolant through the substrate support by operation of said P/N junction.

14. The method of claim 13 wherein said set point temperature is about 60° C. and said coolant temperature is about 50° C.

15. The method of claim 9 further comprising the step of providing a compensation circulation loop between said compensation coolant chamber and the substrate support, and wherein said circulating said compensation coolant from said compensation coolant chamber through the substrate support comprises circulating said compensation coolant through said compensation coolant delivery line and said compensation circulation loop.

16. The method of claim 15 wherein said set point temperature is about 60° C. and said coolant temperature is about 50° C.

17. A method of maintaining a substrate support at a set point temperature in a reaction chamber upon a rise in temperature of the chamber, said reaction chamber connected to a main coolant chamber containing a main coolant and a compensation coolant chamber containing a compensation coolant, comprising the steps of:
obtaining a set point temperature line;
obtaining a main temperature characteristic curve on a first side of said set point temperature line by operating the reaction chamber and the main coolant chamber;
obtaining a temperature compensation characteristic curve on a second side of said set point temperature line by providing a mirror reflection of said main temperature characteristic curve on a second side of said set point temperature line; and
maintaining the substrate support at the set point temperature by operating said compensation coolant chamber in accordance with said temperature compensation characteristic curve.

18. The method of claim 17 wherein said set point temperature line corresponds to a set point temperature of about 60° C.

19. The method of claim 17 further comprising the steps of providing a P/N junction module in thermal contact with the substrate support for sensing a temperature of the substrate support and wherein said operating said compensation coolant chamber comprises controlling flow of the compensation coolant through the substrate support by operation of said P/N junction.

20. The method of claim 19 wherein said set point temperature line corresponds to a set point temperature of about 60° C.
